(19) United States
(12) Patent Application Publication
(10) Pub. No.: US 2012/0132994 A1
(43) Pub. Date: May 31, 2012

(54) HIGH-VOLTAGE SEMICONDUCTOR-ON-INSULATOR DEVICE

(75) Inventors: William F. Clark, JR., Essex Junction, VT (US); Yun Shi, South Burlington, VT (US)

(73) Assignee: INTERNATIONAL BUSINESS MACHINES CORPORATION, Armonk, NY (US)

(21) Appl. No.: 12/955,088

(22) Filed: Nov. 29, 2010

(51) Int. Cl. H01L 27/12; H01L 21/322

(52) U.S. Cl. 257/352; 257/347; 438/151; 257/E27.112; 257/E21.32

(57) ABSTRACT

Embodiments of the present invention relate generally to semiconductor devices and, more particularly, to a structure for high-voltage (HV) semiconductor-on-insulator (SOI) devices and methods for their formation. In one embodiment, the invention provides a semiconductor-on-insulator (SOI) device comprising: a substrate; an insulator layer atop the substrate; a polysilicon layer atop the insulator layer; a device layer atop the polysilicon layer, the device layer comprising: a P-well; an N-well; and an undoped silicon region between the P-well and the N-well; and a trench isolation adjacent one of the P-well and the N-well and extending through the device layer and the polysilicon layer to the insulator layer.

### BACKGROUND

Embodiments of the present invention relate generally to semiconductor devices and, more particularly, to a structure for high-voltage (HV) semiconductor-on-insulator (SOI) devices and methods for their formation.

High-voltage (HV) semiconductor-on-insulator (SOI) devices often suffer from a number of deficiencies resulting in sub-optimal operation or even device failure. For example, FIG. 1 shows a schematic cross-sectional side view of a known HV diode 100 having a typical structure comprising a substrate 10, an insulator layer 20 atop substrate 10, and both a P-well 40 and an N-well 50 within a silicon layer 30 and atop insulator layer 20. Trench isolations 60, 62 extend through silicon layer 30 adjacent N-well 50 and P-well 40, respectively, to insulator layer 20, to isolate the device. A dielectric layer 70, often an oxide, lies atop silicon layer 30, P-well 40, and N-well 50, with openings for the anode 41 and cathode 51.

In operation, a hole accumulation layer 80 often forms atop insulator layer 20 and between P-well 40 and N-well 50. Hole accumulation layer 80 lowers the breakdown voltage of diode 100.

Similar deficiencies exist in other HV SOI devices. For example, FIG. 2 shows a schematic cross-sectional side view of an HV field effect transistor (FET) comprising an N-field oxide FET (NFOXFET) 200 and P-field oxide FET (PFOXFET) 300, with gate electrodes 172, 272 formed atop dielectric layers 170, 270, respectively. Hole accumulation layers 180, 182 again form within NFOXFET 200 and reduce the breakdown voltage (from 100 V to 50 V) of the device. In addition, a hole inversion layer 281, 283 often forms atop insulator layer 120 within PFOXFET 300, effectively forming a source-to-drain short within the device.

### SUMMARY

In one embodiment, the invention provides a semiconductor-on-insulator (SOI) device comprising: a substrate; an insulator layer atop the substrate; a polysilicon layer atop the insulator layer; a device layer atop the polysilicon layer, the device layer comprising: a P-well; an N-well; and an undoped silicon region between the P-well and the N-well; and a trench isolation adjacent one of the P-well and the N-well and extending through the device layer and the polysilicon layer to the insulator layer.

In another embodiment, the invention provides a method of forming a silicon-on-insulator (SOI) device, the method comprising: obtaining an SOI wafer comprising: a substrate; an insulator layer atop the substrate; a polysilicon layer atop the insulator layer; and a silicon layer atop the polysilicon layer; forming a first trench isolation through the silicon layer and the polysilicon layer to the insulator layer; forming a second trench isolation through the silicon layer and the polysilicon layer to the insulator layer; forming a first well in the silicon layer adjacent the first trench isolation; and forming a second well in the silicon layer adjacent the second trench isolation, wherein a portion of the silicon layer separates the first well adjacent the first trench isolation and the second well adjacent the second trench isolation.

The illustrative aspects of the present invention are designed to solve the problems herein described and other problems not discussed, which are discoverable by a skilled artisan.

### BRIEF DESCRIPTION OF THE SEVERAL VIEWS OF THE DRAWINGS

These and other features of this invention will be more readily understood from the following detailed description of the various aspects of the invention taken in conjunction with the accompanying drawings that depict various embodiments of the invention, in which:

FIG. 1 shows a schematic cross-sectional side view of a known diode.

FIG. 2 shows a schematic cross-sectional side view of a known field effect transistor (FET).

FIG. 3 shows a schematic cross-sectional side view of a diode according to an embodiment of the invention.

FIG. 4 shows a schematic cross-sectional side view of a FET according to an embodiment of the invention.

FIGS. 5-7 show schematic cross-sectional side views of the formation of a semiconductor-on-insulator (SOI) wafer according to an embodiment of the invention.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION

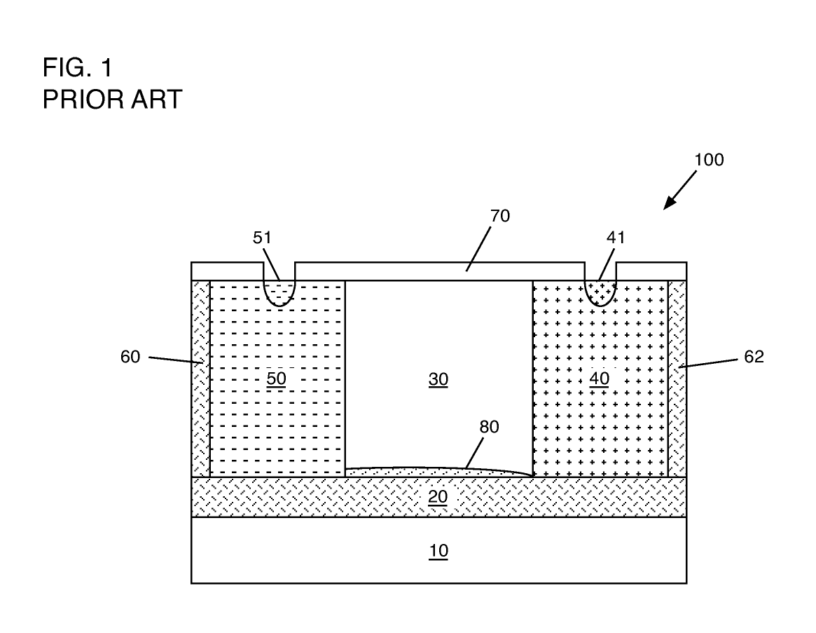

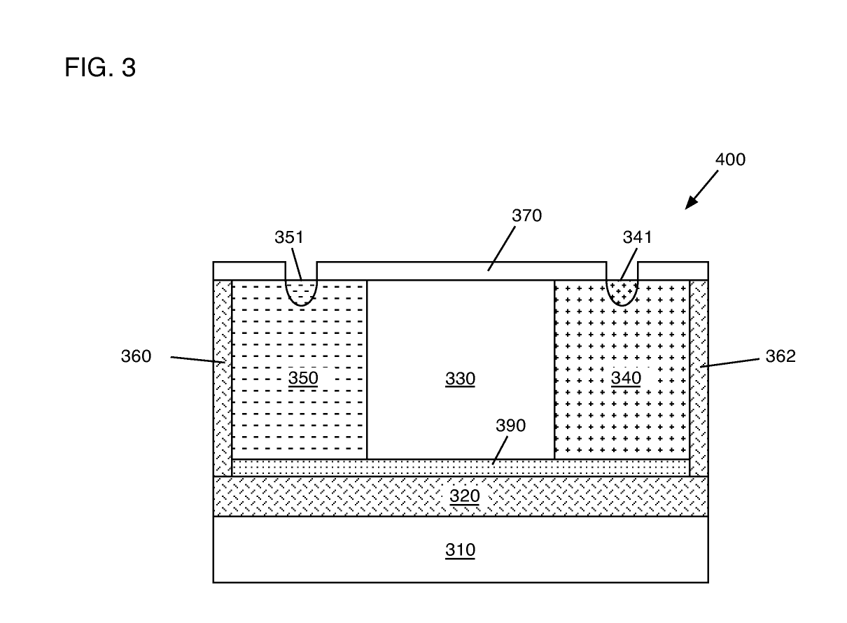

FIG. 3 shows a schematic cross-sectional side view of a high-voltage (HV) diode 400 according to an embodiment of the invention. Here, a polysilicon layer 390 resides beneath the undoped silicon layer 330, P-well 340, and N-well 350, which may be referred to collectively as the device layer. As used herein, “undoped” means a silicon layer containing no dopant or a silicon layer that is lightly doped with a P-type dopant or N-type dopant at a concentration less than the concentration of P-type dopant or N-type dopant in P-well 340 or N-well 350, respectively. That is, undoped silicon layer 330 may include a dopant at a concentration that does not materially alter its function as compared to a silicon layer including no dopant. Trench isolations 360, 362 extend through silicon layer 330 to insulator layer 320. Polysilicon layer 390 prevents the formation of a hole accumulation layer (80 in FIG. 1) atop insulator layer 320. As a consequence, the lowering of the breakdown voltage observed in known devices is avoided.

Substrate 310 may include, but is not limited to, silicon, germanium, silicon germanium, silicon carbide, carbide, mixtures thereof, and those materials consisting essentially of one or more III-V compound semiconductors having a composition defined by the formula Al_{X1}Ga_{X2}In_{X3}As_{Y1}P_{Y2}N_{Y3}Sb_{Y4}, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substrates include II-VI compound semiconductors having a composition Zn_{Al}Cd_{A2}Se_{B1}Te_{B2}, where A1, A2, B1, and B2 are relative proportions each greater than or equal to zero and A1+A2+B1+B2=1 (1 being a total mole quantity). Furthermore, a portion or entire semiconductor substrate may be strained.

Insulator layer 320 and trench isolations 360, 362 may include, for example, silicon nitride (Si₃N₄), silicon oxide (SiO₂), fluorinated SiO₂ (FSG), hydrogenated silicon oxycarbide (SiCOH), porous SiCOH, boro-phosho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, SiLK (a polyarylene ether available from Dow Chemical Corporation), a spin-on silicon-carbon containing polymer material available form JSR Corporation, other low dielectric constant (<3.9) material, or layers thereof.

P-well 340 may include any number of P-type dopants, including, for example, boron, boron difluoride (BF₂), indium, and gallium. N-well 350 may include any number of N-type dopants, including, for example, phosphorous, arsenic, antimony, sulphur, selenium, tin, silicon, and carbon. In some embodiments of the invention, silicon layer 330 may include a single-crystal silicon layer and, as noted above, may be lightly doped with one or more N-type dopant or P-type dopant.

Dielectric layer 370 may include, for example, hafnium silicate (HfSi), hafnium oxide (HfO₂), zirconium silicate (ZrSiOₓ), zirconium oxide (ZrO₂), silicon oxide (SiO₂), silicon nitride (Si₃N₄), silicon oxynitride (SiON), high-k material or any combination of these materials.

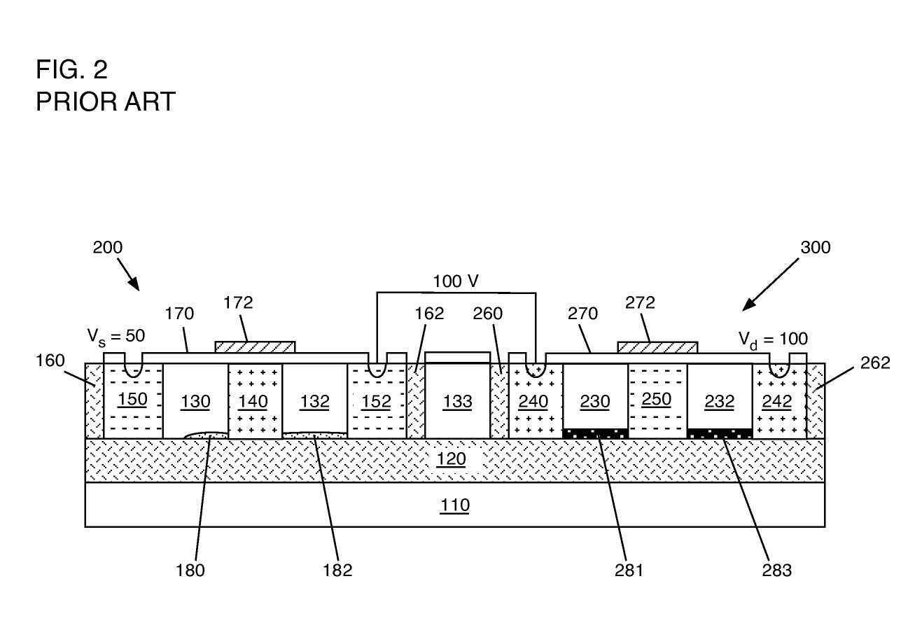

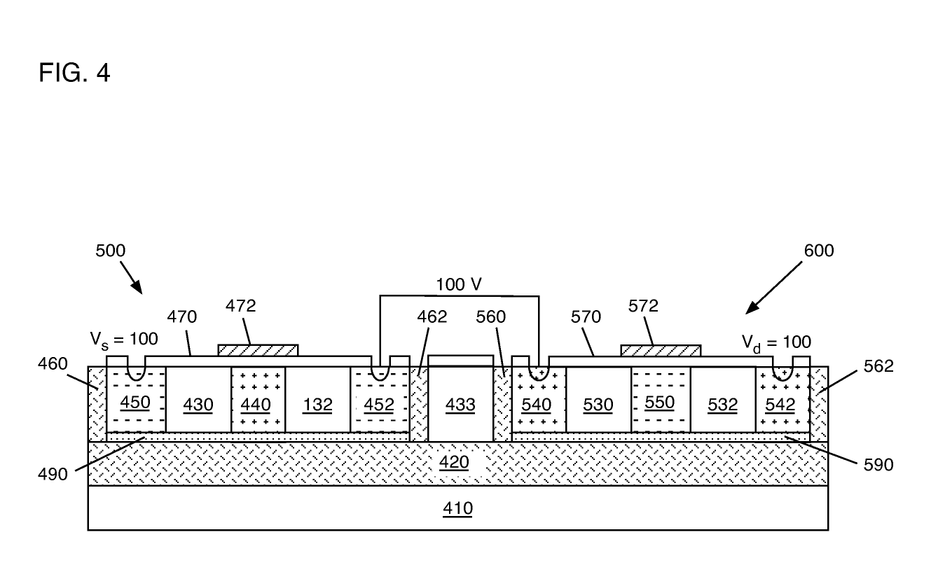

FIG. 4 shows a schematic cross-sectional side view of an HVFET comprising an NFOXFET 500 and PFOXFET 600 according to an embodiment of the invention. A polysilicon layer 490, 590 resides atop insulator layer 420 within each of NFOXFET 500 and PFOXFET 600, respectively. In NFOXFET 500, polysilicon layer 490 prevents formation of a hole accumulation layer (180, 182 in FIG. 2) atop insulator layer 420 and the attendant lowering of breakdown voltage, as described above. In PFOXFET 600, polysilicon layer 590 prevents formation of a hole inversion layer (281, 283 in FIG. 2) and its attendant source-to-drain short.

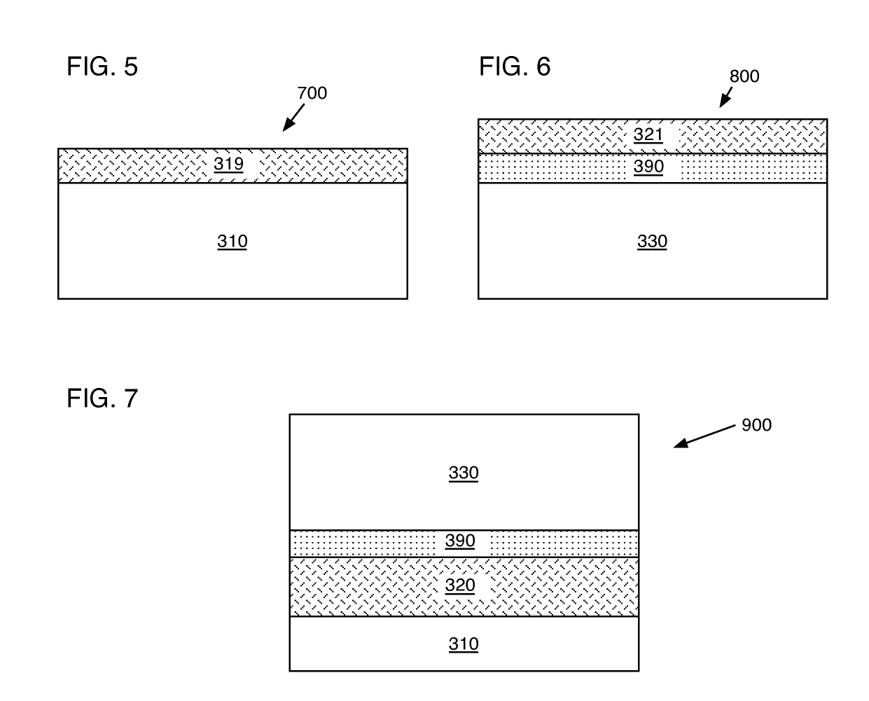

An SOI wafer containing a polysilicon layer between insulator and silicon layers, and in which any number of SOI devices may be formed, may be formed or obtained by any number of methods or techniques, as will be apparent to one skilled in the art. For example, FIGS. 5-7 show the formation of such an SOI wafer according to an embodiment of the invention. In FIG. 5, a first wafer 700 comprises an insulator layer 319 atop a substrate 310 and, in FIG. 6, a second wafer 800 comprises an insulator layer 321 atop a polysilicon layer 390, which lies atop a silicon substrate 330.

SOI wafer 900 in FIG. 7 may be formed by inverting either first wafer 700 or second wafer 800 and bonding their insulator layers 319, 321, respectively, to form a single insulator layer 320. Insulator layers 319, 321 may be bonded by any number of methods or techniques, including, for example, thermal growth or deposition.

As will be recognized by one skilled in the art, SOI devices that may be formed according to embodiments of the invention include, for example, an HV diode 400 (FIG. 3), NFOXFET 500 (FIG. 4), or PFOXFET 600 (FIG. 4). For example, once SOI wafer 900 is obtained, trench isolations (e.g., 360, 362 in FIG. 3) may be formed through silicon layer 330 and polysilicon layer 390 to insulator layer 320 and one or more P-wells (e.g., 340 in FIG. 3) and/or one or more N-wells (e.g., 350 in FIG. 3) may be formed in silicon layer 330 adjacent trench isolations 360, 362. Various other device components (e.g., gate dielectrics, gate electrodes, etc.) may similarly be formed, depending on the device being formed.

Such device components and structures may be formed using any known or later-developed technique or method. For example, trench isolations may be formed using photolithographic techniques such as isotropic etching or reactive ion etching followed by deposition of a filler material by, for example, chemical vapor deposition or epitaxial growth.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The foregoing description of various aspects of the invention has been presented for purposes of illustration and description. It is not intended to be exhaustive or to limit the invention to the precise form disclosed, and obviously, many modifications and variations are possible. Such modifications and variations that may be apparent to a person skilled in the art are intended to be included within the scope of the invention as defined by the accompanying claims.

What is claimed is:

1. A semiconductor-on-insulator (SOI) device comprising:
a substrate;
an insulator layer atop the substrate;
a polysilicon layer atop the insulator layer;
a device layer atop the polysilicon layer, the device layer comprising:
a P-well;
an N-well; and
an undoped silicon region between the P-well and the N-well; and
a trench isolation adjacent one of the P-well and the N-well and extending through the device layer and the polysilicon layer to the insulator layer.

2. The SOI device of claim 1, wherein the trench isolation is adjacent the P-well.

3. The SOI device of claim 2, further comprising:
an additional trench isolation adjacent the N-well and extending through the device layer and the polysilicon layer to the insulator layer.

4. The SOI device of claim 2, wherein the device layer further includes:
an additional P-well; and
an additional undoped silicon region between the N-well and the additional P-well.

5. The SOI device of claim 4, further comprising:
an additional trench isolation adjacent the additional P-well and extending through the device layer and the polysilicon layer to the insulator layer.

6. The SOI device of claim 1, wherein the trench isolation is adjacent the N-well.

7. The SOI device of claim 6, further comprising:
an additional N-well;
an additional undoped silicon region between the P-well and the additional N-well.

8. The SOI device of claim 7, further comprising:
an additional trench isolation adjacent the additional N-well and extending through the device layer and the polysilicon layer to the insulator layer.

9. The SOI device of claim 1, wherein the substrate is selected from a group consisting of: silicon, germanium, silicon germanium, silicon carbide, carbide, and mixtures thereof.

10. The SOI device of claim 1, wherein the P-well includes at least one dopant selected from a group consisting of: boron, boron difluoride (BF₂), and indium, and the N-well includes at least one dopant selected from a group consisting of: phosphorous, arsenic, and antimony.

11. The SOI device of claim 1, wherein the silicon layer of the device layer includes a single-crystal silicon layer.

12. A method of forming a silicon-on-insulator (SOI) device, the method comprising:
obtaining an SOI wafer comprising:
a substrate;
an insulator layer atop the substrate;
a polysilicon layer atop the insulator layer; and
a silicon layer atop the polysilicon layer;
forming a first trench isolation through the silicon layer and the polysilicon layer to the insulator layer;
forming a second trench isolation through the silicon layer and the polysilicon layer to the insulator layer;
forming a first well in the silicon layer adjacent the first trench isolation; and
forming a second well in the silicon layer adjacent the second trench isolation,
wherein a portion of the silicon layer separates the first well adjacent the first trench isolation and the second well adjacent the second trench isolation.

13. The method of claim 12, wherein the forming the first well in the silicon layer adjacent the first trench isolation includes forming a P-well in the silicon layer adjacent the first trench isolation and the forming the second well in the silicon layer adjacent the second trench isolation includes forming an N-well in the silicon layer adjacent the second trench isolation.

14. The method of claim 13, wherein the SOI device includes a diode.

15. The method of claim 12, wherein the forming the first well in the silicon layer adjacent the first trench isolation includes forming a P-well in the silicon layer adjacent the first trench isolation and the forming the second well in the silicon layer adjacent the second trench isolation includes forming a P-well in the silicon layer adjacent the second trench isolation.

16. The method of claim 15, further comprising:
forming an N-well in the silicon layer between the P-well adjacent the first trench isolation and the P-well adjacent the second trench isolation;
forming a gate dielectric layer over the N-well; and
forming a gate electrode on the gate dielectric layer,
wherein a first portion of the silicon layer separates the N-well from the P-well adjacent the first trench isolation and a second portion of the silicon layer separates the N-well from the P-well adjacent the second trench isolation.

17. The method of claim 12, wherein the forming the first well in the silicon layer adjacent the first trench isolation includes forming a N-well in the silicon layer adjacent the first trench isolation and the forming the second well in the silicon layer adjacent the second trench isolation includes forming a N-well in the silicon layer adjacent the second trench isolation.

18. The method of claim 17, further comprising:
forming a P-well in the silicon layer between the N-well adjacent the first trench isolation and the N-well adjacent the second trench isolation;
forming a gate dielectric layer over the P-well; and
forming a gate electrode on the gate dielectric layer,
wherein a first portion of the silicon layer separates the P-well from the N-well adjacent the first trench isolation and a second portion of the silicon layer separates the P-well from the N-well adjacent the second trench isolation.

19. The method of claim 12, wherein:
the substrate is selected from a group consisting of: silicon, germanium, silicon germanium, silicon carbide, carbide, and mixtures thereof;
the second well includes at least one dopant selected from a group consisting of: boron, boron difluoride (BF₂), and indium; and
the first well includes at least one dopant selected from a group consisting of: phosphorous, arsenic, and antimony.

20. The method of claim 12, wherein the silicon layer includes a single-crystal silicon layer.
